(19) United States
(12) Patent Application Publication
(10) Pub. No.: US 2015/0214480 A1
(43) Pub. Date: Jul. 30, 2015

(54) RESISTIVE RANDOM-ACCESS MEMORY AND METHOD FOR FABRICATING THE SAME

(71) Applicant: Winbond Electronics Corp., Taichung City (TW)

(72) Inventors: Po-Yen HSU, New Taipei City (TW); Ting-Ying SHEN, Chiayi City (TW); Ming-Chung CHIANG, Yongjing Township (TW)

(73) Assignee: Winbond Electronics Corp., Taichung City (TW)

(21) Appl. No.: 14/165,941

(22) Filed: Jan. 28, 2014

(51) Int. Cl. H01L 45/00

(52) U.S. Cl. CPC H01L 45/1253; H01L 45/1233; H01L 45/1608; H01L 45/1666

(57) ABSTRACT

The disclosure provides a method for fabricating a resistive random-access memory, including: providing a substrate; forming an inter-layer dielectric layer over the substrate; forming a stop layer over the inter-layer dielectric layer; forming an opening through the stop layer and the inter-layer dielectric layer; forming a bottom electrode in the opening, wherein the bottom electrode is coplanar with the stop layer; depositing a dielectric layer over the bottom electrode and the stop layer; depositing a top electrode material over the dielectric layer; and patterning the top electrode material and the dielectric layer to define a top electrode and an inter-electrode dielectric layer under the top electrode, wherein the top electrode has a second surface opposite to a first surface of the bottom electrode, arid the second surface has a greater area than the first surface.

### CROSS REFERENCE TO RELATED APPLICATIONS

This application claims priority of Taiwan Patent Application No. 102134697, filed on Sep. 16, 2013, the entirety of which is incorporated by reference herein.

### BACKGROUND

1. Technical Field

The disclosure relates to a resistive random-access memory and method for fabricating the same.

2. Description of the Related Art

A non-volatile memory has the advantage of retaining data storage without a power supply and has become an essential memory element for many electronic products in normal operation. Resistive random access memory (RRAM) is a non-volatile memory which has been developed recently. RRAM has many advantages such as low writing-in operation voltage, short writing-in and eliminating time, long memory time, non-destructive read-out, multi-state memory, structure simplicity, and requiring only a small area. RRAM has a great potential for application in personal computers and other electronic devices in the future.

However, before mass production of RRAM, there are still lots of challenges to overcome. One of the challenges is the variation of the current-voltage (I-V) characteristics of RRAM. The variation is the resulted of alternative possible pathways of conductive filaments between the top electrodes and the bottom electrodes. An electrode with a greater area will produce more possible pathways for conductive filaments, thus increasing the variation of the I-V characteristics of RRAM. A direct way to minimize the variation is to reduce the area of the electrode.

On the other hand, when forming bottom electrode material in a conventional RRAM, pillar crystalline structures are inherently formed on the surface of the bottom electrode material, resulting in non-uniform deposition of the subsequent inter-electrode dielectric layer, which in turn affects the formation of the filament pathway and increases the variation of the characteristics of RRAM.

### SUMMARY

The disclosure provides a method for fabricating a resistive random-access memory, including: providing a substrate; forming an inter-layer dielectric layer over the substrate; forming a stop layer over the inter-layer dielectric layer; forming an opening through the stop layer and the inter-layer dielectric layer; forming a bottom electrode in the opening, wherein the bottom electrode is coplanar with the stop layer; depositing a dielectric layer over the bottom electrode and the stop layer; depositing a top electrode material over the dielectric layer; and patterning the top electrode material and the dielectric layer to define a top electrode and an inter-electrode dielectric layer under the top electrode, wherein the top electrode has a second surface opposite to a first surface of the bottom electrode, and the second surface has a greater area than the first surface.

The disclosure also provides a resistive random-access memory, including: a substrate; an inter-layer dielectric layer disposed over the substrate; a stop layer disposed over the inter-layer dielectric layer; an opening through the stop layer and the inter-layer dielectric layer; a bottom electrode disposed in the opening, wherein the bottom electrode is coplanar with the stop layer; an inter-electrode dielectric layer disposed over the bottom electrode and extending over a portion of the stop layer; and a top electrode disposed over the inter-electrode dielectric layer, wherein the top electrode has a second surface opposite to a first surface of the bottom electrode, and the second surface has a greater area than the first surface.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A-1H are cross-sectional views of an example RRAM 100 at fabrication stages in accordance with some embodiments; and

FIGS. 2A-2E are cross-sectional views of an example RRAM 200 at fabrication stages in accordance with another embodiments.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In this specification, expressions such as “overlying the substrate”, “above the layer”, or “on the film” simply denote a relative positional relationship with respect to the surface of a base layer, regardless of the existence of intermediate layers. Accordingly, these expressions may indicate not only the direct contact of layers, but also, a non-contact state of one or more laminated layers. It is noted that in the accompanying drawings, like and/or corresponding elements are denoted to by like reference numerals.

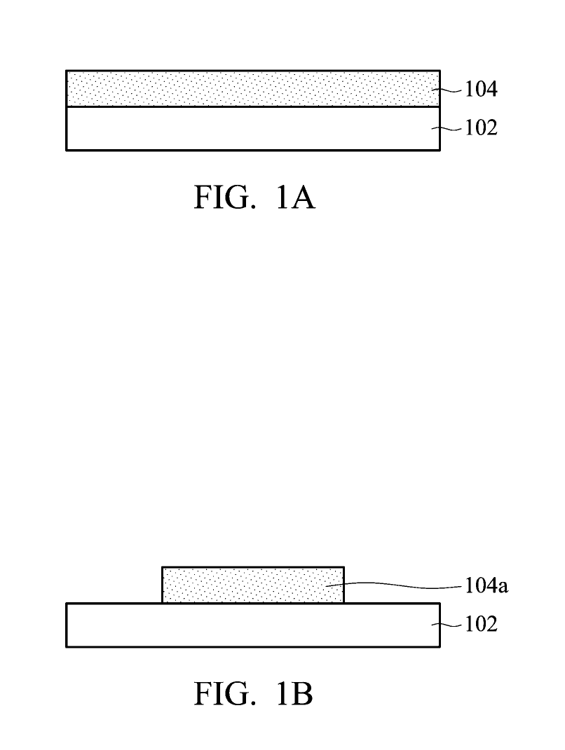

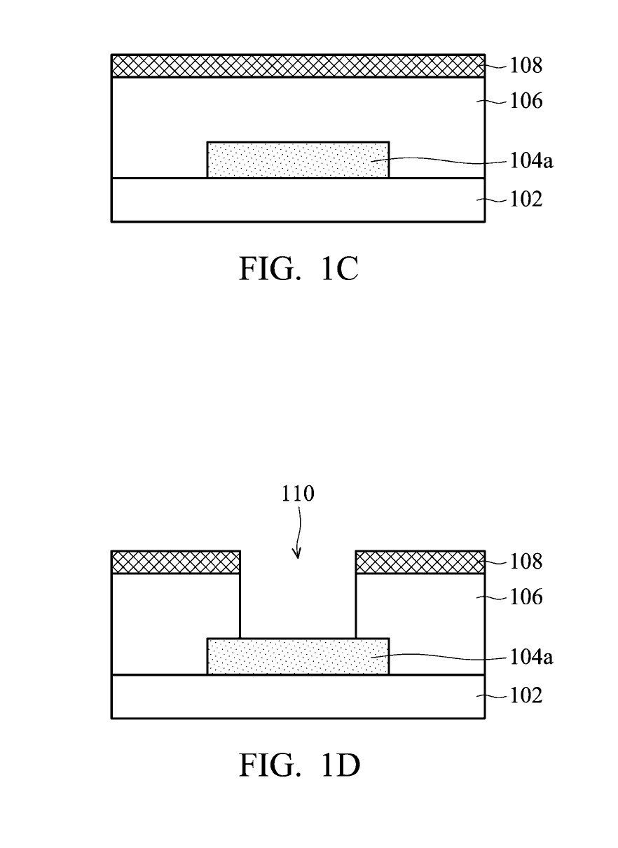

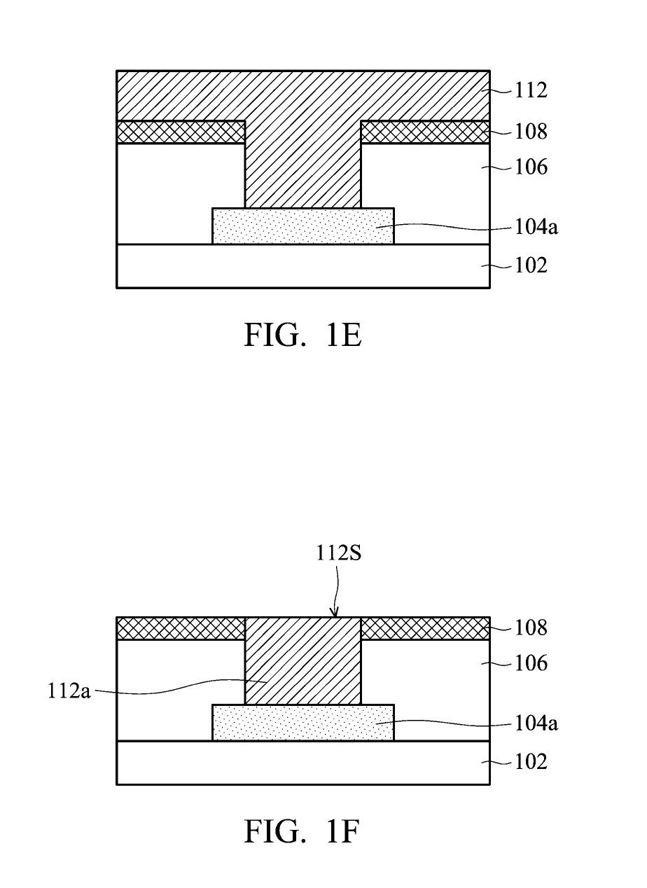

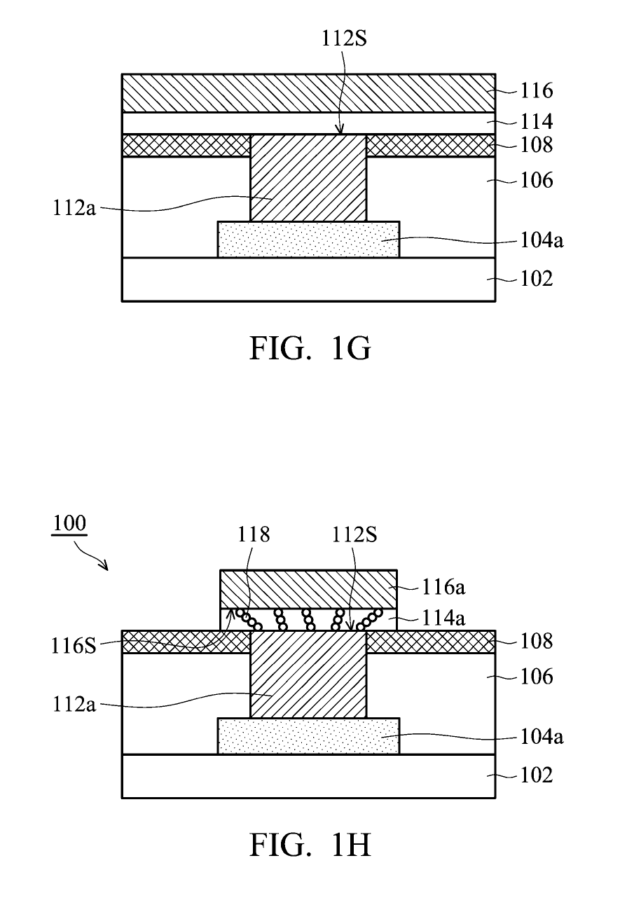

FIGS. 1A-1H are cross-sectional views of an example RRAM 100 at fabrication stages in accordance with some embodiments. Referring to FIG. 1A, a conductive material 104 is formed over a substrate 102. The substrate 102 may be a Si substrate, a SiGe substrate, a SiC substrate, a silicon-on insulator (SOT) substrate, a multi-layered substrate, a gradient substrate, or a hybrid orientation substrate. In one embodiment, the substrate 102 is a Si wafer. The conductive material 104 may be W, Cu, Al, Ag, Au, or any other suitable conductive materials (such as doped polysilicon). Next, referring to FIG. 1B, the conductive material 104 is patterned to form conductive layer 104a. In one embodiment of the present disclosure, the conductive material 104 may be patterned by lithography and dry etch processes (such as reactive ion etching).

Next, referring to FIG. 1C, an inter-layer dielectric layer 106 is formed over the substrate 102, and a stop layer 108 over the inter-layer dielectric layer 106. The inter-layer dielectric layer 106 may include SiO, SiN, SiON, low-k dielectrics, or any other suitable dielectric materials. In sonic embodiments, the stop layer 108 is a nitrogen-containing material, such as SiN, or SiON. The inter-layer dielectric layer 106 and the stop layer 108 may be formed by methods such as chemical vapor deposition (CVD) or spin on coating.

Referring to FIG. 1D, after forming the inter-layer dielectric layer 106 and the stop layer 108, an opening 110 is formed through the inter-layer dielectric layer 106 and the stop layer 108. The opening 110 exposes a portion of the conductive layer 104a. Methods for forming the opening 110 includes dry etch, such as RIE. It should be noted that before proceeding to the next step, a liner layer (not shown) may be optionally formed over a bottom and a sidewall of the opening 110.

Next, referring to FIG. 1E, a bottom electrode material 112 is formed in the opening 110 and over the stop layer 108. The bottom electrode material 112 may be Ti, TiN, Pt, W, Al, or any other suitable electrode materials. Methods for forming the bottom electrode material include, but are not limited to, physical vapour deposition (PVD), atomic layer deposition (AM), metal organic chemical vapour deposition (MOCVD), or any other suitable deposition processes.

Next, referring to FIG. 1F, a portion he bottom electrode material 112 is removed to form a bottom electrode 112a in the opening 110. The removal of a portion of the bottom electrode material 112 may be accomplished by planarizing the bottom electrode material (such as by chemical mechanical polishing) with the stop layer 108 as a polishing stop such that the top surface 112S of the bottom electrode 112a is coplanar with the top surface of the stop layer 108. The planarization may simultaneously remove the liner layer (if any). In contrast to the conventional RRAM, the present disclosure may effectively form a flat top surface 112S of the bottom electrode 112a by forming the bottom electrode material 112 in the opening 108 and planarizing the bottom electrode material 112 with the stop layer 108 as a polishing stop. The flat top surface may improve the uniformity of the inter-electrode dielectric layer and the top electrode, and reduce or eliminate the formation of pillar crystalline structures on the surface of the bottom electrode of the conventional RRAM and as a result, reduce the variation of the I-V characteristics of RRAM.

Referring to FIG. 1 after forming the bottom electrode 112a, a dielectric layer 114 and a top electrode material 116 are formed sequentially over the stop layer 108 and the bottom electrode 112a. The dielectric layer 114 may include SiO, SiN, SiON, high-k dielectrics, or any other suitable dielectric materials. The high-k dielectrics may include metal oxide, such as oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu. In one embodiment, the dielectric layer 114 may be HfO₂. The top electrode material 116 may include Ti, TiN, Pt, W, Al, or any other suitable electrode materials.

Next, referring to FIG. 1H, the dielectric layer 114 and the top electrode material 116 are patterned to respectively define an inter-electrode dielectric layer 114a and a top electrode 116a to complete the manufacture of RRAM 100. The inter-electrode dielectric layer 114a and the top electrode 116a partially extend onto the stop layer 108 surrounding the opening 110. The dielectric layer 114 and the top electrode material 116 may be patterned by lithography and dry etch processes (such as reactive ion etching). In sonic embodiments of the present disclosure, the top electrode 116a has a bottom surface 116S opposite to a top surface 112S of the bottom electrode 112a, and the bottom surface 116S of the top electrode 116a has a greater area than the top surface 112S of the bottom electrode 112a. This asymmetric MIM structure may effectively reduce the formation area of the filament structure 118 on the top surface 112S of the bottom electrode 112a, thus greatly reducing the variation of the I-V characteristics of RRAM.

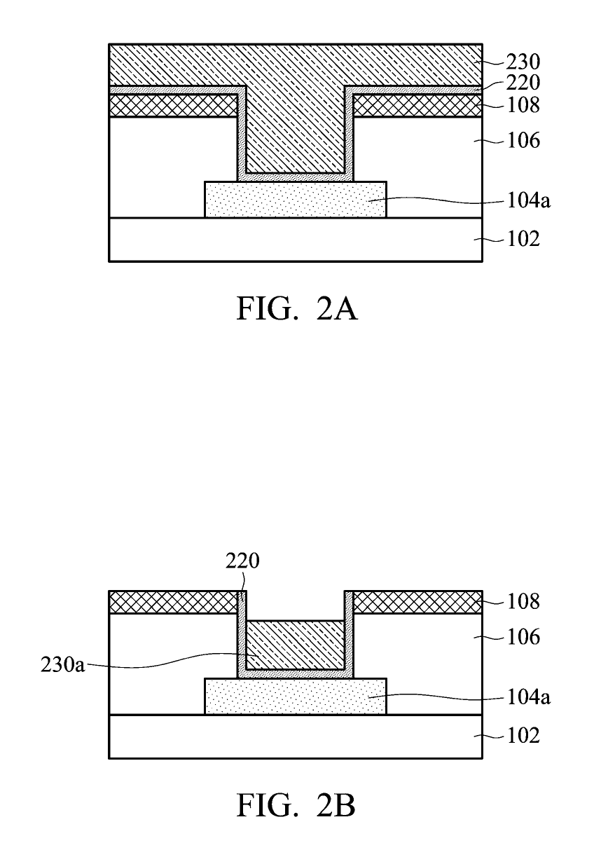

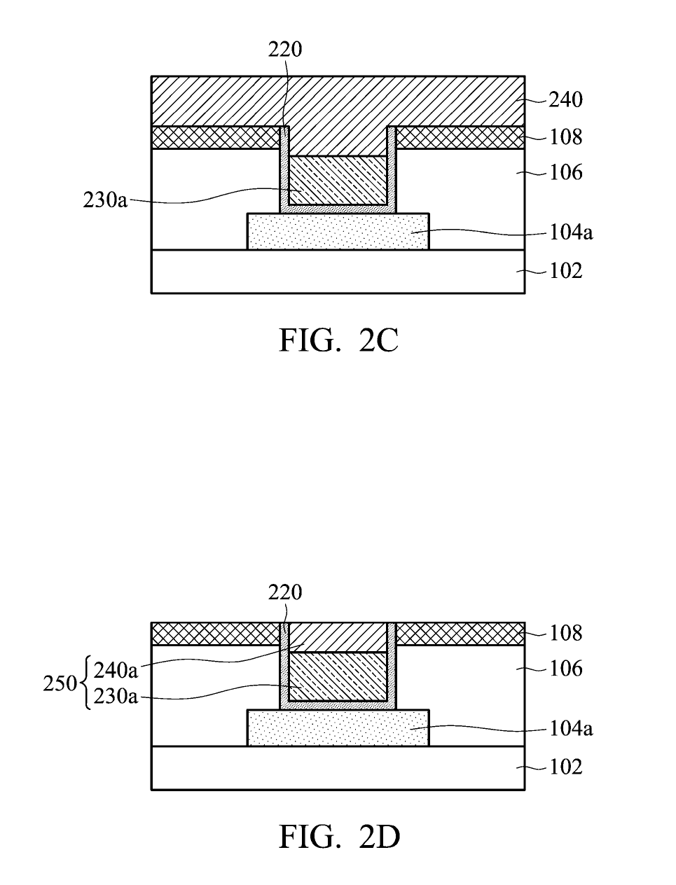

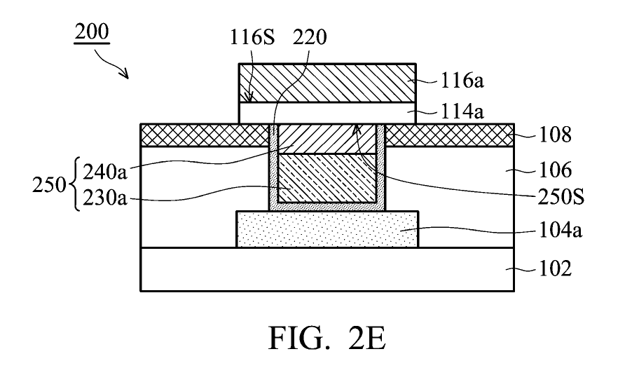

In addition to the aforementioned embodiments, the RRAM of the present disclosure may utilize a composite bottom electrode in accordance with the material selection of the inter-electrode dielectric layer 114a. In the following, RRAM 200 of another embodiment of the present disclosure will he described by referring to FIGS. 2A-2E. Note that the same or like elements corresponding to those of RRAM 100 are denoted by like reference numerals. A description of the same manufacturing process will not be repeated for the sake of brevity.

Refer to FIG. 2A, which is the cross-sectional view of the fabrication stages after that shown in FIG. 1D. In one embodiment, after forming the opening 110, a liner lay 220 may optionally be conformally formed in the opening 110 over the stop layer 108 to reduce the stress. The liner layer 220 may be a conductive material, such as Ti, TiN, or a combination thereof. The liner layer 220 electrically contacts the conductive layer 104a. Next, a first bottom electrode material 230 is formed in the opening 110 and over the stop layer 108. The first bottom electrode material 230 may include W, Cu, Al, or any other suitable electrode materials. In one embodiment, the first bottom electrode material 230 is W. Methods for forming the first bottom electrode material 230 include, but are not limited to, PVD, ALD, MOCVD, or any other suitable deposition processes.

Next, referring to FIG. 2B, the first bottom electrode material 230 on the stop layer 108 and a portion of the first bottom electrode material 230 in the opening 110 are removed to form a first bottom electrode 230a. The methods for removing the first bottom electrode material 230 may include dry etching, such as RIE. In the process shown in FIG. 2B, stop layer 108 is used as an etch stop layer, and this process may simultaneously remove a portion of the liner layer 220 (if any) outside the opening 110.

Next, as shown in FIG. 2C, a second bottom electrode material 240 is formed over the first bottom electrode 230a and the stop layer 108. The second bottom electrode material 240 may include Ti, Pt, TiN, or any other suitable electrode materials. In one embodiment, the second bottom electrode material 240 is TiN.

Next, referring to FIG. 2D, a portion of the second bottom electrode material 240 is removed to form a second bottom electrode 240a in the opening 110 to complete the composite bottom electrode 250 of this embodiment. As shown in FIG. 2D, the bottom electrode 250 includes the first bottom electrode 230a and the second bottom electrode 240a. The removal of a portion of the second bottom electrode material 240 may be accomplished by planarizing the second bottom electrode material 240 (such as chemical mechanical polishing) with the stop layer 108 as a polishing stop such that the top surface 250S of the bottom electrode 250 is coplanar with the top surface of the stop layer 108.

Finally, as shown in FIG. 2E, an inter-electrode dielectric layer 114a and a top electrode 116a are formed over the stop layer 108 and the bottom electrode 250 to complete the RRAM 200 of the embodiment. Methods for forming the inter-electrode dielectric layer 114a and the top electrode 116a are the same as in FIGS. 1G-1H and the corresponding paragraphs, and will not be described again herein. The top electrode 116a of the RRAM 200 has a bottom surface 116S opposite to a top surface 250S of the bottom electrode 250, and the bottom surface 116S of the top electrode 116a has a greater area than the top surface 250S of the bottom electrode 250. It should be noted that the embodiment may effectively reduce the resistance of the RRAM by forming the composite bottom electrode., so as to enhance the performance of the RRAM.

The present disclosure may form a bottom electrode with a flat surface by forming the bottom electrode material in the opening and planarizing the bottom electrode with the stop layer as a polishing stop to remove the pillar crystalline structures inherently formed on the bottom electrode material. The flat top surface may improve the uniformity of the inter-electrode dielectric layer and the top electrode, and reduce or eliminate the variation of the I-V characteristics of RRAM. Besides, the asymmetric MIM structure may effectively reduce the formation area of the conductive filament structure on the top surface of the bottom electrode, thus greatly reducing the variation of the I-V characteristics of RRAM.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A method for fabricating a resistive random-access memory, comprising:
providing a substrate;
forming an inter-layer dielectric layer over the substrate;
forming a stop layer over the inter-layer dielectric layer;
forming an opening through the stop layer and the inter-layer dielectric layer;
forming a bottom electrode in the opening, wherein the bottom electrode is coplanar with the stop layer;
depositing a dielectric layer over the bottom electrode and the stop layer;
depositing a top electrode material over the dielectric layer; and
patterning the top electrode material and the dielectric layer to define a top electrode and an inter-electrode dielectric layer under the top electrode, wherein the top electrode has a second surface opposite to a first surface of the bottom electrode, and the second surface has a greater area than the first surface.

2. The method for fabricating a resistive random-access memory as claimed in claim 1, wherein the forming of the bottom electrode comprises:
depositing a bottom electrode material to completely fill the opening and cover the stop layer; and
polishing the bottom electrode material with the stop layer as a polishing stop to remove the bottom electrode material outside the opening.

3. The method for fabricating a resistive random-access memory as claimed in claim 1, wherein the forming of the bottom electrode comprises:
depositing a first bottom electrode material to completely fill the opening and cover the stop layer;
recessing the first bottom electrode material such that the opening becomes partially filled by the first bottom electrode material;
depositing a second bottom electrode material to refill the opening and cover the stop layer; and
polishing the second bottom electrode material with the stop layer as a polishing stop to remove the second bottom electrode material outside the opening.

4. The method for fabricating a resistive random-access memory as claimed in claim 3, wherein the first bottom electrode material comprises W, Cu, Al, or a combination thereof, and the second bottom electrode material comprises TiN, Ti, Pt, or a combination thereof.

5. The method for fabricating a resistive random-access memory as claimed in claim 1, wherein the stop layer comprises SiN, SiON, or a combination thereof.

6. The method for fabricating a resistive random-access memory as claimed in claim 1, wherein before the forming of the inter-layer dielectric layer, further comprising:
forming a conductive layer over the substrate; and
patterning the conductive layer, wherein the conductive layer is exposed in the step of forming the opening,

7. The method for fabricating a resistive random-access memory as claimed in claim 1, before the forming of the bottom electrode, further comprising:
forming a liner layer over a bottom and a sidewall of the opening.

8. A resistive random-access memory, comprising:
a substrate;
an inter-layer dielectric layer disposed over the substrate;
a stop layer disposed over the inter-layer dielectric layer;
an opening through the stop layer and the inter-layer dielectric layer;
a bottom electrode disposed in the opening, wherein the bottom electrode is coplanar with the stop layer;
an inter-electrode dielectric layer disposed over the bottom electrode and extending over a portion of the stop layer; and
a top electrode disposed over the inter-electrode dielectric layer, wherein the top electrode has a second surface opposite to a first surface of the bottom electrode, and the second surface has a greater area than the first surface.

9. The resistive random-access memory as claimed in claim 8, wherein the bottom electrode comprises:
a first bottom electrode material partially filling the opening; and
a second bottom electrode material disposed over the first bottom electrode material, wherein a top surface of the second bottom electrode material is coplanar with the stop layer.

10. The resistive random-access memory as claimed in claim 9, wherein the first bottom electrode material comprises W, Cu, Al, or a combination thereof, and the second bottom electrode material comprises TiN, Ti, Pt, or a combination thereof.

11. The resistive random-access memory as claimed in claim 8, wherein the stop layer comprises SIN, SiON, or a combination thereof.

12. The resistive random-access memory as claimed in claim 8, further comprising:
a conductive layer disposed under the inter-layer dielectric layer, wherein the opening exposes a portion of the conductive layer.

13. The resistive random-access memory as claimed in claim 8, further comprising:
a liner layer lining along a bottom and a sidewall of the opening, wherein the bottom electrode is disposed over the liner layer in the opening.
